(19) United States
(12) Patent Application Publication
(10) Pub. No.: US 2025/0374409 A1
(43) Pub. Date: Dec. 4, 2025

(54) SYSTEM, DEVICE, METHOD, AND PROGRAM FOR PROVIDING PERFORMANCE PRODUCTION SIMULATION USING DYNAMIC LIGHT-EMITTING PATTERNS

(71) Applicant: FANLIGHT CO., LTD., Seoul (KR)

(72) Inventors: Kyung Il CHOI, Seoul (KR); Jung Min CHOI, Seoul (KR)

(73) Assignee: FANLIGHT CO., LTD., Seoul (KR)

(21) Appl. No.: 19/299,847

(22) Filed: Aug. 14, 2025

Related U.S. Application Data
(63) Continuation of application No. PCT/KR2024/000606, filed on Jan. 12, 2024.

(30) Foreign Application Priority Data
Feb. 15, 2023 (KR) 10-2023-0019871

(51) Int. Cl. H05B 47/175; H05B 47/155; H05B 47/18; H05B 47/19

(52) U.S. Cl. CPC H05B 47/1985; H05B 47/155; H05B 47/184; H05B 47/19; H05B 47/196

(57) ABSTRACT

The present disclosure relates to a stage production simulation providing system using dynamic light emission patterns, wherein when a specific performance venue seating layout is selected from at least one performance venue seating layout through a user interface and a specific dynamic light emission pattern is selected from dynamic light emission patterns, the selected specific performance venue seating layout is divided into a plurality of sections based on the selected dynamic light emission pattern, and the user interface can be controlled so that a stage production effect corresponding to the selected dynamic light emission pattern is implemented on the specific performance venue seating layout divided into the plurality of sections.

### CROSS-REFERENCE TO RELATED APPLICATIONS

This application is a continuation of International Application No. PCT/KR2024/000606 filed on Jan. 12, 2024, which claims priority to Korean Patent Application No. 10-2023-0019871 filed on Feb. 15, 2023, the entire contents of which are herein incorporated by reference.

### TECHNICAL FIELD

The present disclosure relates to a stage production system, and more particularly, to a stage production simulation providing system that uses dynamic light emission patterns.

### BACKGROUND

Recently, stage production effects have been provided by controlling lighting using devices or light sticks held by audience members during performances.

Since each light-emitting device is controlled manually, the range of possible effects is restricted.

Therefore, applying technology that uses various dynamic light emission patterns is expected to provide a wider variety of effects more conveniently. However, no such technology has been disclosed yet.

### SUMMARY OF THE INVENTION

### Problems to be Solved by the Invention

The present disclosure is conceived to provide a stage production simulation providing system that uses dynamic light emission patterns.

However, the problems to be solved by the present disclosure are not limited to the above-described problems. Although not described herein, other problems to be solved by the present disclosure can be clearly understood by a person with ordinary skill in the art from the following descriptions.

### Means for Solving the Problems

To achieve the above-described technical objective, a stage production simulation providing apparatus that uses dynamic light emission patterns includes a memory that stores at least one performance venue seating layout and a plurality of dynamic light emission patterns that respectively represents various stage production effects to be implemented by allowing light emission of a group of light-emitting devices corresponding to positions of individual seats in the at least one performance venue; a display unit that displays a user interface configured to virtually implement the stage production effects corresponding to the dynamic light emission patterns on the seating layout; and a processor that receives a control command corresponding to a specific control pattern requested from a lighting console device, and controls the user interface to simulate the stage production effect corresponding to the received control command, wherein when a specific seating layout is selected from the at least one performance venue seating layout and a specific dynamic light emission pattern is selected from the dynamic light emission patterns through the user interface, the processor divides the selected seating layout into a plurality of sections based on the selected dynamic light emission pattern, and controls the user interface to implement a stage production effect corresponding to the selected dynamic light emission pattern on the seating layout divided into the plurality of sections.

To achieve the above-described technical objective, a method for providing a stage production simulation using dynamic light emission patterns to be performed by a stage production apparatus includes a process of storing at least one performance venue seating layout and a plurality of dynamic light emission patterns that respectively represents various stage production effects to be implemented by allowing light emission of a group of light-emitting devices corresponding to positions of individual seats in the at least one performance venue; a process of receiving a control command corresponding to a specific control pattern requested from a lighting console device; and a process of controlling a user interface to simulate the stage production effect corresponding to the received control command. Wherein the process of controlling a user interface includes a process of displaying the user interface configured to virtually implement stage production effects corresponding to the dynamic light emission patterns on the at least one performance venue seating layout; when a specific seating layout is selected from the at least one performance venue seating layout and a specific dynamic light emission pattern is selected from the dynamic light emission patterns through the user interface, a process of dividing the selected seating layout into a plurality of sections based on the selected dynamic light emission pattern; and a process of controlling the user interface to implement a stage production effect corresponding to the selected dynamic light emission pattern on the seating layout divided into the plurality of sections.

In addition, a computer program stored in a computer-readable recording medium for executing a method for implementing the present disclosure may be further provided.

In addition, a computer-readable recording medium recording a computer program for executing a method for implementing the present disclosure may be further provided.

### Effects of the Invention

According to any one of the above-described means for solving the problems of the present disclosure, it is possible to provide a stage production simulation providing system that uses dynamic light emission patterns.

The effects of the present disclosure are not limited to the above-described effects. Although not described herein, other effects of the present disclosure can be clearly understood by a person with ordinary skill in the art from the following descriptions.

### BRIEF DESCRIPTION OF THE DRAWINGS

FIG. 1 is a schematic diagram illustrating a stage production simulation providing system that uses dynamic light emission pattern according to embodiments of the present disclosure.

FIG. 2 is a block diagram illustrating a stage production apparatus that uses dynamic light emission pattern according to embodiments of the present disclosure.

FIG. 3 is a flowchart showing a method for providing a stage production simulation using dynamic light emission patterns according to embodiments of the present disclosure.

FIG. 4 is a diagram illustrating an example of a memory in which dynamic light emission patterns and seating layouts of performance venues are stored.

FIG. 5 is a diagram illustrating an example of a user interface for stage production effect simulation.

FIG. 6 is a diagram illustrating an example of dynamic light emission pattern #4.

FIG. 7 is a diagram illustrating an example of a stage and a seating layout of performance venue #7 stored in the memory.

FIG. 8 and FIG. 9 are diagrams illustrating examples in which the seating layout of performance venue #7 is divided into a plurality of sections.

FIG. 10 is a diagram illustrating an example in which dynamic light emission patterns are applied to the entire performance venue.

FIG. 11 is a diagram illustrating an example in which light-emitting devices located at the seats of the performance venue, as shown in FIG. 10, emit light in the form of pixels.

FIG. 12 is a diagram illustrating an example in which light-emitting devices held by audience members seated at the respective seats in the performance venue emit light under the conditions of light emission patterns shown in FIG. 10.

FIG. 13 is a diagram illustrating an example of calculating shape information of performance venue #7 selected through the user interface.

FIG. 14 is a diagram illustrating an example of calculating pattern scores of dynamic light emission patterns.

FIG. 15 is a diagram illustrating an example of calculating the suitability of each dynamic light emission pattern for stage production in performance venue #7.

FIG. 16 is a diagram illustrating an example of displaying, in a second list, dynamic light emission patterns that satisfy predetermined suitability conditions based on the calculated suitability.

### DETAILED DESCRIPTION OF THE INVENTION

Like reference numerals refer to like elements throughout the present disclosure. Not all details of embodiments of the present disclosure are described herein, and description of general art to which the present disclosure pertains and overlapping descriptions between embodiments are omitted. Components indicated by terms including “unit,” “module,” “member,” and “block” herein may be implemented by software or hardware. According to different embodiments, a plurality of units, modules, members, and blocks may be implemented by a single element, or each of a single unit, a single module, a single member, and a single block may include a plurality of elements.

Throughout the whole document, a certain part being “connected” to another part includes the certain part being directly connected to the other part or being indirectly connected to the other part. Indirect connection includes being connected through a wireless communication network.

Also, a certain part “including” a certain element signifies that the certain part may further include another element instead of excluding other elements unless particularly indicated otherwise.

Throughout the whole document, the term “on” that is used to designate a position of one element with respect to another element includes both a case that the one element is adjacent to the other element and a case that any other element exists between these two elements.

The terms “first”, “second”, etc. can be used to describe different components, but the components should not be construed as limited by these terms.

A singular expression includes a plural expression unless it is clearly construed in a different way in the context.

A reference numeral provided to each process for convenience of description is used to identify each process. The reference numerals are not for describing an order of the processes, and the processes may be performed in an order different from that shown in the drawings unless a specific order is clearly described in the context.

Hereinafter, the operation principle and embodiments of the present disclosure will be described with reference to the accompanying drawings.

A stage production apparatus according to the present disclosure includes various devices capable of performing arithmetic processing to provide results to a user. For example, the stage production apparatus according to the present disclosure may include all of a computer, a server device, and a portable device, or may adopt any one of them.

Herein, the computer may include, for example, a notebook computer, a desktop, a laptop, a tablet PC or a slate PC equipped with a web browser.

The server device is a server for processing information by performing communication with an external device, and includes an application server, a computing server, a database server, a file server, a game server, a mail server, a proxy server, a web server, and the like.

The portable device is a wireless communication device providing portability and mobility, and includes all kinds of handheld-based wireless communication devices, such as a personal communications system (PCS), a global system for mobile communications (GSM), a personal digital cellular (PDC), a personal handyphone system (PHS), a personal digital assistant (PDA), an international mobile telecommunication (IMT)-2000, a code division multiple access (CDMA)-2000, a W-code division multiple access (W-CDMA), wireless broadband internet (WiBro) device, a smartphone, and the like, and a wearable device, such as a watch, a ring, a bracelet, an ankle bracelet, a necklace, glasses, contact lenses, or a head-mounted device (HMD).

Functions associated with artificial intelligence according to the present disclosure are performed by a processor 110 and a memory 150. The processor 110 may include one or more processors 110. In this case, the one or more processors 110 may include a general-use processor 110 such as a central processing unit (CPU), an application processor (AP) or a digital signal processor (DSP), a graphics-dedicated processor such as a graphics processing unit (GPU) or a vision processing unit (VPU), or an artificial intelligence-dedicated processor such as a neural processing unit (NPU). The one or more processors 110 control input data to be processed according to a predefined operation rule stored in the memory 150 or an artificial intelligence model. Alternatively, when the one or more processors 110 are artificial intelligence-dedicated processors 110, the artificial intelligence-dedicated processors 110 may be designed as hardware structures specialized in processing of a certain artificial intelligence model.

The predefined operation rule or the artificial intelligence model may be made by learning. Herein, the making of the predefined operation rule or the artificial intelligence model by learning should be understood to mean that a basic artificial intelligence model is trained using a plurality of pieces of training data by a learning algorithm, thereby creating the predefined operation rule or the artificial intelligence model to achieve a desired feature (or purpose). The above-described learning may be made by a device in which artificial intelligence according to the present disclosure is performed or by a separate server and/or a system 10. Examples of the learning algorithm may include supervised learning, unsupervised learning, semi-supervised learning, or reinforcement learning, but are not limited thereto.

The artificial intelligence model may include a plurality of neural network layers. A plurality of weight values may be allocated to the plurality of neural network layers, and a neural network operation may be performed through a result of performing an operation on a previous layer and the plurality of weight values. The plurality of weight values of the plurality of neural network layers may be optimized by a result of training the artificial intelligence model. For example, the plurality of weight values may be updated to reduce or minimize a loss value or a cost value obtained from the artificial intelligence model during a learning process. The artificial neural network may include, but is not limited to, a deep neural network (DNN), e.g., a convolutional neural network (CNN), a DNN, a recurrent neural network (RNN), a restricted Boltzmann machine (RBM), a deep belief network (DBN), a bidirectional recurrent DNN (BRDNN), or deep Q-networks.

According to the embodiments of the present disclosure, the processor 110 may implement artificial intelligence. Artificial intelligence refers to an artificial neural network-based machine learning method that allows a machine to learn by imitating human biological neurons. Artificial intelligence methodology may be divided according to leaning methods thereof and includes: supervised learning with a determined solution (i.e., output data) to a problem (i.e., input data) due to providing the input data and output data together as training data; unsupervised learning with no determined solution (i.e., output data) to a problem (i.e., input data) due to providing only the input data without the output data; and reinforcement learning with learning to proceed in a direction of maximally increasing rewards given in an external environment every time an action is taken in a current state. Further, the artificial intelligence methodology may be divided according to structures thereof, and widely used structures of deep learning technology may be divided into a convolutional neural network (CNN), a recurrent neural network (RNN), a transformer, a generative adversarial network (GAN), etc.

The present device may include an artificial intelligence model. The artificial intelligence model may be a single artificial intelligence model, and may also be implemented with a plurality of artificial intelligence models. The artificial intelligence model may be composed of a neural network (or an artificial neural network) and may include a statistical learning algorithm imitating biological neurons in machine learning and cognitive science. The neural network may refer to the overall model with problem-solving capabilities, wherein artificial neurons (i.e., nodes) forming a network by coupling synapses are configured to change synaptic coupling strength through learning. The neurons in the neural network may include combinations of weight values or biases. The neural network may include one or more layers composed of one or more neurons or nodes. For example, the device may include an input layer, a hidden layer, and an output layer. The neural network constituting the device may infer a result (i.e., an output) to be predicted from an arbitrary input by changing weight values of neurons through learning.

The processor 110 may create a neural network, train (or learn) the neural network, perform a calculation based on received input data, generate an information signal based on the calculation result, or retrain the neural network. The neural network models may include various types of models of a convolution neural network (CNN) such as GoogleNet, AlexNet, and VGGNet, a region with convolution neural network (R-CNN), a region proposal network (RPN), a recurrent neural network (RNN), a stacking-based deep neural network (S-DNN), a state-space dynamic neural network (S-SDNN), a deconvolution network, a deep belief network (DBN), a restricted Boltzman machine (RBM), a fully convolutional network, a long short-term memory (LSTM) network, a classification network, and the like, but are not limited thereto. The processor 110 may include one or more processors 110 for performing calculations according to the neural network models. For example, the neural networks may include a deep neural network.

The neural networks may include a convolutional neural network (CNN), a recurrent neural network (RNN), a perceptron, a multilayer perceptron, a feedforward (FF) neural network, a radial basis function (RBF) network, a deep feed forward (DFF) neural network, a long short term memory (LSTM) neural network, a gated recurrent unit (GRU), an auto encoder (AE), a variational auto encoder (VAE), a denoising auto encoder (DAE), a sparse auto encoder (SAE), a Markov Chain (MC) neural network, a Hopfield network (HN), a Boltzmann machine (BM), a restricted Boltzmann machine (RBM), a deep belief network (DBN), a deep convolutional network (DCN), a deconvolutional network (DN), a deep convolutional inverse graphics network (DCIGN), a generative adversarial network (GAN), a liquid state machine (LSM), an extreme learning machine (ELM), an echo state network (ESN), a deep residual network (DRN), a differential neural computer (DNC), a neural Turing machine (NTM), a capsule network (CN), a Kohonen network (KN), and an attention network (AN), but are not limited thereto, and a person with ordinary skill in the art will understand that the neural networks may include any neural networks.

According to the embodiments of the present disclosure, the processor 110 may be configured to use various artificial intelligence structures and algorithms of a convolution neural network (CNN) such as GoogleNet, AlexNet, and VGGNet, a region with convolution neural network (R-CNN), a region proposal network (RPN), a recurrent neural network (RNN), a stacking-based deep neural network (S-DNN), a state-space dynamic neural network (S-SDNN), a deconvolution network, a deep belief network (DBN), a restricted Boltzman machine (RBM), a fully convolutional network, a long short-term memory (LSTM) network, a classification network, generative modeling, explainable AI, continual AI, representation learning, AI for material design, algorithms of BERT, SP-BERT, MRC/QA, Text Analysis, a dialog system, GPT-3, and GPT-4 for natural language processing, algorithms of visual analytics, visual understanding, and video Synthesis for vision processing, algorithms of anomaly detection and prediction for ResNet data intelligence, time-series forecasting, optimization, recommendation, data creation, etc., but are not limited thereto. Hereinafter, the embodiments of the present disclosure will be described in detail with reference to the accompanying drawings.

Before describing the present disclosure, the meaning of terms used in the specification will be simply described. The description of the terms is for helping understanding of the specification, and when the terms are not used in order to limit the present disclosure definitely, it should be noted that the terms are not used for limiting the technical scope of the present disclosure.

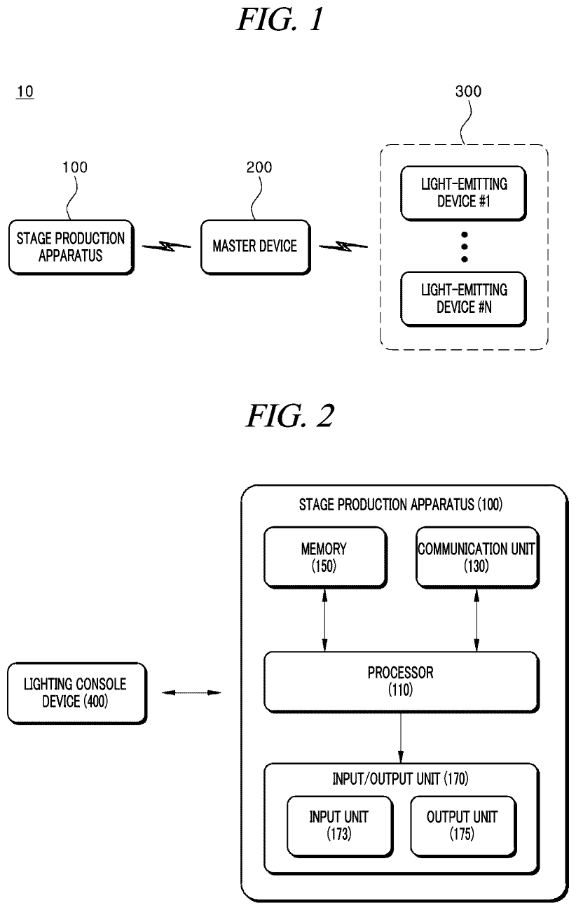

FIG. 1 is a schematic diagram illustrating a stage production simulation providing system 10 that uses dynamic light emission pattern according to embodiments of the present disclosure.

Referring to FIG. 1, the stage production system 10 that uses dynamic light emission pattern according to embodiments of the present disclosure includes a stage production apparatus 100, a master device 200, and a plurality of light-emitting devices 300.

However, in some embodiments, the stage production system 10 may include fewer or more components than those illustrated in FIG. 1.

In the embodiments of the present disclosure, the stage production apparatus 100 is configured to virtually demonstrate how dynamic light emission patterns will be applied in a performance venue by conducting a simulation of stage production using dynamic light emission patterns. After the simulation, when the stage production is executed, the master device 200 outputs control signals to control the light-emitting devices 300 in the venue and thus implements the dynamic light emission patterns in the performance venue.

In the embodiments of the present disclosure, the stage production apparatus 100 may also be configured to include the master device 200.

Accordingly, the stage production apparatus 100 is not only capable of simulating how the dynamic light emission patterns will be applied in the performance venue, but can also control the master device 200 to implement various types of dynamic light emission patterns for stage production such as cheering in audience seats.

Hereinafter, the components for the basic operation of the stage production apparatus 100 will be described briefly.

The stage production apparatus 100 may perform a function for simulating and executing stage production by controlling a user interface or the light-emitting devices 300. The stage production apparatus 100 may be one of electronic devices such as a mobile phone, a smart phone, a laptop computer, a digital broadcasting device, a personal digital assistant (PDA), a portable multimedia player (PMP), a navigation system, a slate PC, a tablet PC, an ultrabook, and a wearable device (for example, a smart watch, smart glasses, a head mounted display (HMD), or the like). The stage production apparatus 100 may include all electronic devices capable of installing and executing an application related to the embodiments, may include some of configurations of the electronic devices, or may be implemented in various forms capable of interworking therewith.

In the embodiments of the present disclosure, the stage production apparatus 100 may be one of software for PC and an electronic device such as MA Lighting grandMA2, grandMA3, ETC EOS, ETC ION, ETC GIO, Chroma Q Vista, High End HOG, High End Fullboar, Avolites Sapphire Avolites Tiger, Chamsys MagicQ, Obsidian control systems Onyx, Martin M6, Martin M1, Nicolaudie Sunlite, ESA, ESA2, Lumidesk, SunSuite, Arcolis, Daslight, LightRider, MADRIX, DJ LIGHT STUDIO, DISCO-DESIGNER VJ STUDIO, Stagecraft, Lightkey, or the like.

In the embodiments of the present disclosure, the stage production apparatus 100 is configured to provide a stage production simulation using dynamic light emission patterns. The stage production apparatus 100 may be an electronic device that implements virtual simulation for implementing lighting effects, software that runs on the electronic device, or a complex device that combines the software and the electronic device.

For example, the user may input an electronic signal corresponding to a scene to be simulated on the stage production apparatus 100. After the simulation, when stage production is executed through an input/output unit 170, the stage production apparatus 100 may convert the input electronic signal to conform to the protocol of a light emission control signal in order for the master device 200 to output a control signal for controlling the light-emitting devices 300.

In the embodiments of the present disclosure, the stage production apparatus 100 may include appropriate software or a computer program for controlling the light-emitting devices 300. For example, the stage production apparatus 100 may include DMX512, RDM, Art-Net, sACN, ETC-Net2, Pathport, Shownet, or KiNET as a protocol for controlling the light-emitting devices 300. The stage production apparatus 100 may transmit a data signal (e.g., a light emission control signal) in an appropriate format such as DMX512, Art-Net, sACN, ETC-Net2, Pathport, Shownet or KiNET. The stage production apparatus 100 may generate a light emission control signal for controlling the light-emitting devices 300. The light emission control signal may be broadcast to the light-emitting devices 300, and thus one or more light-emitting devices 300 may emit light depending on the light emission control signal. The light emission control signal may include information about an emission state (e.g., an emission color, a brightness value, a blinking speed, or the like).

In the embodiments of the present disclosure, the stage production apparatus 100 may include a plurality of input/output ports. The stage production apparatus 100 may include an input/output port corresponding to or related to a specific data signal format or protocol. For example, the stage production apparatus 100 may include a first port dedicated to DMX512 and RDM data input/output and a second port dedicated to Art-Net and sACN, ETC-Net2, Pathport, Shownet, KiNET data input/output. The DMX512, RDM, Art-Net, sACN, ETC-Net2, Pathport, Shownet and KiNET protocols are widely known as control protocols for stage lighting installations. According to the embodiments of the present disclosure, the stage production apparatus 100 may plan more flexible control for the light-emitting devices 300 by using control protocols such as DMX512, RDM, Art-Net, SACN, ETC-Net2, Pathport, Shownet, and KiNET.

According to the embodiments of the present disclosure, the stage production apparatus 100 may generate a production object based on factors such as the size of a performance venue, the seating layout of the venue, and the production shape, which refers to a light emission pattern of the light-emitting devices 300 within the audience area during the performance, or may provide user-friendly tools for generating such production objects. When a production object is generated in the stage production apparatus 100, the origin point of the production object may be set in advance or may be defined at a specific position. For example, the origin point may be set or defined as a characteristic part of the production object, the midpoint of the outline of the production object, and the center of mass (COM) of the production object. When the origin point of a specific production object has already been set, the stage production apparatus 100 may skip an operation of newly setting the origin point of the same production object.

According to the embodiments of the present disclosure, the stage production apparatus 100 may create a lighting map for representing the production shape or may support user tools for creating a lighting map. The lighting map is a production map including possible production scenarios that can be represented as production objects. A stage director can creates dynamic effects by selectively activating a plurality of light-emitting devices 300 located in the audience area of the performance venue by using at least a portion of the lighting map.

According to the embodiments of the present disclosure, the lighting map may include a plurality of partial objects, and each partial object may form a single production object or may form a part of a single production object. In other words, a production object may include at least one partial object.

According to the embodiments of the present disclosure, the stage production apparatus 100 may create a masking map in which expression levels are defined radially from the center of the object or may support user tools for creating the masking map. The expression levels of the masking map may be set to maintain the shape of the origin point defined at the center of the object, and the expression levels are sequentially determined by their positional relationship with the central coordinates.

The master device 200 may be provided for efficient signal transmission in the performance venue. The master device 200 may include a database DB. The master device 200 may receive a control signal from the stage production apparatus 100 and provide the control signal to transmitters, including information from its database DB, or directly provide the control signal to the light-emitting device 300. The master device 200 may be an electronic device such as a mobile phone, a smart phone, a laptop computer, a digital broadcasting device, a personal digital assistant (PDA), a portable multimedia player (PMP), a navigation system, a slate PC, a tablet PC, an ultrabook, and a wearable device (for example, a smart watch, smart glasses, a head mounted display (HMD), or the like), but is not limited thereto. The master device 200 may include at least one transmitter (not shown).

The master device 200 may perform functions such as outputting or amplifying a light emission control signal for stage production. For example, the master device 200 may include a communication device such as an antenna.

In an embodiment, the master device 200 may include a plurality of transmitters, and the number and installation positions of the transmitters may be determined based on conditions such as the size and structure of the performance venue.

The transmitters according to the present disclosure may have directivity. A stage planner may arrange the transmitters during a performance planning stage, taking into account the specifications of the transmitters to be used in the performance. Accordingly, the light-emitting device 300 may receive a light emission control signal from a transmitter having identification information corresponding to identification information of a transmitter previously stored in the light-emitting device 300.

In the embodiments of the present disclosure, the stage production apparatus 100 may transmit light emission control signals for stage production to the master device 200, and the master device 200 may convert the light emission control signals into wireless control signals. By outputting the light emission control signals through the transmitters installed in the performance venue, the light-emitting devices 300 within the venue can receive the light emission control signals.

Under the control of the stage production apparatus 100, the light-emitting devices 300 may perform a function of producing various types of light emission patterns in real time or according to predetermined control information.

In the embodiments of the present disclosure, the light-emitting device 300 may include a light-emitting element such as a liquid crystal display (LCD) or light-emitting diode (LED) or may be connected to the light-emitting element. The light-emitting device 300 may be a device including any electronic device capable of wireless communication. The light-emitting device 300 may be a small cheering tool held by an audience member at the performance venue for sports events or concerts. For example, the light-emitting device 300 may be a mobile phone, the wireless light-emitting device 300, a lighting stick, a lighting bar, a lighting ball, a lighting panel, and a device equipped with a light source that is wirelessly controllable. In the present disclosure, the light-emitting device 300 may be referred to as a lighting device, a receiver, a controlled device, a slave, or a slave lighting device. Also, the light-emitting device 300 may include a wearable device to be attached to and/or worn on a part of the body, such as wrist or chest.

In the embodiments of the present disclosure, the light-emitting device 300 may interpret the light emission control signal received from the transmitter based on previously stored identification information of the transmitter and may emit light. Specifically, the light-emitting device 300 may compare the pre-stored identification information of the transmitter with identification information of the transmitter included in the light emission control signal. When the pre-stored identification information of the transmitter is the same as the identification information included in the light emission control signal, the light-emitting device 300 may emit light to correspond to a light emission pattern included in the corresponding light emission control signal.

In the embodiments of the present disclosure, the light-emitting device 300 may be the common name for a plurality of light-emitting devices 300. For example, the light-emitting device 300 may include a first light-emitting device 300, a second light-emitting device 300, and the like. For example, a plurality of light-emitting devices 300 may be located in the performance venue, and the first light-emitting device 300 located in a first section may receive a control signal from a first transmitter and the second light-emitting device 300 located in a second section may receive a control signal from a second transmitter. Accordingly, even though a plurality of light-emitting devices 300 is located in the performance venue, distributed processing of control signals may be possible.

The stage production system 10 according to the embodiments of the present disclosure enables the user to select stage production suitable for the performance venue and atmosphere by simulating dynamic light emission patterns in advance before applying them to the venue. Also, the stage production system 10 allows for stage production without requiring the user to configure each seat individually, by applying dynamic light emission patterns to different sections of the seating area and transmitting the corresponding control signals to the respective sections.

Although conventional lighting console devices (such as grandMA2) offer limited visual simulation effects, they are designed for lighting control and thus support at most several thousand control simulations. As control methods shift from wired to wireless, the operation modes, group configurations, and usage information are referenced differently in real time.

The stage production simulation providing system 10 using dynamic light emission patterns according to the embodiments of the present disclosure interprets control commands not supported by conventional lighting devices. This allows it to individually or collectively control numerous cheering sticks (from a few to tens of thousands) with identical information simultaneously. Thus, it can produce a visual effect where they can operate either identically or differently.

Hereinafter, the system 10, apparatus, method and program for providing a stage production simulation using dynamic light emission patterns according to embodiments of the present disclosure will be described in more detail with reference to other accompanying drawings.

FIG. 2 is a block diagram illustrating the stage production apparatus 100 that uses dynamic light emission pattern according to embodiments of the present disclosure.

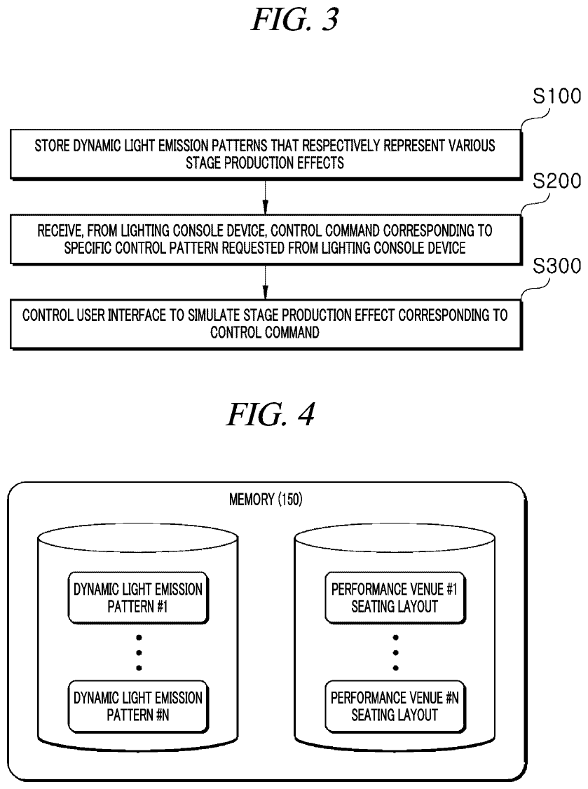

FIG. 3 is a flowchart showing a method for providing a stage production simulation using dynamic light emission patterns according to embodiments of the present disclosure.

Referring to FIG. 2, the stage production apparatus 100 includes the processor 110, a communication unit 130, the memory 150, and the input/output unit 170. The input/output unit 170 includes an input unit 173 and an output unit 175.

However, in some embodiments, the stage production apparatus 100 may include fewer or more components than those illustrated in FIG. 2.

The processor 110 may simulate dynamic light emission patterns on the seats of the performance venue by controlling operations related to virtual stage effects.

The processor 110 may be implemented with the memory 150 that stores data about an algorithm or a program based on the algorithm for controlling the operations of components within the present apparatus, and at least one processor 110 that performs the above-described operations using the data stored in the memory 150. In some cases, the memory 150 and the processor 110 may be implemented as separate chips. Alternatively, the memory 150 and the processor 110 may be implemented as a single chip.

Further, the processor 110 may control one or a combination of the above-described components to implement various embodiments according to the present disclosure to be described below with reference to the drawings on the present apparatus.

The processor 110 may generally control the overall operation of the present apparatus as well as the operations related to the application program. The processor 110 may provide or process information or a function appropriate to the user by processing signals, data, information, and the like, which are input or output through the above-described components, or by executing the application program stored in the memory 150.

Further, the processor 110 may control at least some of the components of the present apparatus to execute the application program stored in the memory 150. Furthermore, the processor 110 may operate a combination of at least two or more of the components included in the present apparatus to execute the application program.

The communication unit 130 may include one or more modules that connect the stage production apparatus 100 to one or more networks.

The communication unit 130 may include one or more components that enable communication with external devices. For example, the communication unit 130 may include at least one of a broadcast reception module, a wired communication module, a wireless communication module, a short-range communication module, and a position information module.

The wired communication module may include various wired communication modules, such as a local area network (LAN) module, a wide area network (WAN) module, or a value added network (VAN) module, as well as various cable communication modules, such as a universal serial bus (USB), high definition multimedia interface (HDMI), digital visual interface (DVI), recommended standard 232 (RS-232), power line communication, or plain old telephone service (POTS).

The wireless communication module may include not only a WiFi module and a wireless broadband module, but also wireless communication modules supporting various wireless communication schemes, such as global system for mobile communication (GSM), code division multiple access (CDMA), wideband code division multiple access (WCDMA), universal system mobile telecommunications system (UMTS), time division multiple access (TDMA), long term evolution (LTE), 4G, 5G, and 6G.

The wireless communication module may include a wireless communication interface including an antenna and a transmitter for transmitting signals. The wireless communication module may further include a signal conversion module that modulates a digital control signal output from the processor 110 into an analog radio signal via the wireless communication interface, under the control of the processor 110.

The short-range communication module may support short-range communication using at least one of Bluetooth™, Radio Frequency Identification (RFID), Infrared Data Association (IrDA), Ultra-Wideband (UWB), ZigBee, Near Field Communication (NFC), Wi-Fi (Wireless-Fidelity), Wi-Fi Direct, and Wireless USB (Wireless Universal Serial Bus) technologies.

The memory 150 may store data supporting various functions of the present apparatus. The memory 150 may store a number of application (or application programs) running on the present apparatus, data and instructions for operating the present apparatus. At least some of the applications may be provided for basic functions of the present apparatus. The applications may be stored in the memory 150, installed on the present apparatus and executed by the processor 110 to perform operations (or functions).

The memory 150 may store data supporting various functions of the present apparatus, programs for operating the processor 110, and input/output data (e.g., music files, still images, moving images, or the like). Also, the memory 150 may store a number of applications (or application programs) running on the present apparatus, data and instructions for operating the present apparatus. At least some of the applications may be downloaded from an external server via wireless communication.

The memory 150 may include at least one type of storage medium among a flash memory type, a hard disk type, a solid state disk type, an Silicon Disk Drive (SDD) type, a multimedia card micro type, a card type memory (e.g., SD or XD memory 150), random access memory (RAM), static random access memory (SRAM), read-only memory (ROM), electrically erasable programmable read-only memory (EEPROM), programmable read-only memory (PROM), magnetic memory 150, magnetic disk, and optical disk. Further, the memory 150 may be a database that is separate from the present apparatus but connected thereto in a wired or wireless manner.

Further, the memory 150 may include a plurality of processes for providing a stage production simulation using dynamic light emission patterns.

The input unit 173 is configured to input image information (or signals), audio information (or signals), data, or information input by the user. The input unit 173 may include at least one camera, at least one microphone, and at least one input unit 173. Voice or image data collected by the input unit 173 may be analyzed and processed as a user control command.

The input unit 173 is configured to receive information from the user. When information is input through the input unit 173, the processor 110 may control the operation of the present apparatus in response to the input information. The input unit 173 may include a hardware type physical key (for example, a button, a dome switch, a jog wheel, a jog switch, or the like that is located on at least one of a front surface, a rear surface, and a side surface of the present apparatus), and a software type touch key. For example, the touch key may include a virtual key, a soft key, or a visual key that is displayed on a touchscreen type display unit through software processing, and may include a touch key that is disposed at a part, except for the touchscreen. Meanwhile, the virtual key or the visual key can be displayed in various forms on the touchscreen, and may include, for example, a graphic, a text, an icon, a video, or a combination thereof.

The output unit 175 is configured to generate visual, auditory, or tactile output. The output unit 175 may include at least one of a display unit, a sound output unit 175, a haptic module, and a light output unit 175. The display unit and a touch sensor may be integrated or arranged in a layered structure to form a touch screen. The touchscreen may function as the input unit 173 that provides an input interface between the present apparatus and the user, and may also provide an output interface between the present apparatus and the user.

In the embodiments of the present disclosure, the output unit 175 may include a display unit as a means for image output. The display unit displays (outputs) information that is processed by the present apparatus. For example, the display unit may display execution screen information of an application program (for example, an application) running on the present apparatus, or user interface (UI) or graphic user interface (GUI) information according to the execution screen information.

The display unit presents a user interface that virtually implements stage production effects corresponding to dynamic light emission patterns on a seating layout.

In the embodiments of the present disclosure, the processor 110 may output various types of information for simulating stage production to a plurality of areas of the display unit, and the display unit may include a plurality of image output devices.

Referring to FIG. 3, the method for providing a stage production simulation using dynamic light emission patterns according to embodiments of the present disclosure may be performed through the following processes.

The processor 110 stores, in the memory 150, a seating layout of at least one performance venue and dynamic light emission patterns (S100). The dynamic light emission patterns respectively represent various stage production effects to be implemented by allowing light emission of a group of light-emitting devices 300 corresponding to the positions of individual seats in the seating layout.

The processor 110 receives, from a lighting console device 400 (for example, grandMA2, grandMA3, etc.), a control command corresponding to a specific control pattern requested from the lighting console device 400 (S200).

The control command may be in a data format such as DMX512, RDM, Art-Net, sACN, ETC-Net2, Pathport, Shownet, MA-Net2, and MA-Net3, which are applicable for interpreting and outputting control patterns.

In the embodiments of the present disclosure, the lighting console device 400 and a stage production apparatus 100 may be connected to each other in a wired or wireless manner.

In the embodiments of the present disclosure, the control command corresponding to a specific control pattern may include a control signal for a specific dynamic light emission pattern for operating the light-emitting devices 300.

The processor 110 controls the user interface to simulate a stage production effect corresponding to the received control command (S300).

Specifically, the processor 110 may simulate the stage production effect as follows.

The processor 110 presents, on the screen, a user interface that virtually implements stage production effects corresponding to dynamic light emission patterns on the seating layout.

The processor 110 may control light emission of a plurality of light-emitting devices 300 in the performance venue. Thus, the stage production effects based on the dynamic light emission patterns can be reproduced in the venue.

Further, the processor 110 may control the user interface to simulate the stage production effects based on the dynamic light emission patterns before they are actually applied to the performance venue. Thus, the simulation can be displayed on the screen of the stage production apparatus.

The processor 110 receives a signal for selecting a seating layout of a specific performance venue and a signal for selecting a specific dynamic light emission pattern through the communication unit.

The processor 110 divides the selected seating layout of the performance venue into a plurality of sections.

Specifically, when a specific seating layout is selected from among at least one seating layout and a specific dynamic light emission pattern is selected from among a plurality of dynamic light emission patterns through the user interface, the processor 110 divides the selected seating layout of the venue into a plurality of sections based on the selected dynamic light emission pattern.

In an embodiment, when a seating layout of a performance venue is stored in the memory, the processor 110 may select the seating layout and divide it into a plurality of sections. Also, when seating layouts of a plurality of performance venues are stored, the processor 110 may select a seating layout of a specific venue and divide it into a plurality of sections.

The processor 110 controls the user interface to implement the stage production effect corresponding to the selected dynamic light emission pattern on the seating layout divided into the plurality of sections.

FIG. 4 is a diagram illustrating an example of the memory 150 in which dynamic light emission patterns and seating layouts of performance venues are stored.

Referring to FIG. 4, the memory 150 according to the embodiments of the present disclosure stores therein a seating layout of at least one performance venue and a plurality of dynamic light emission patterns.

The dynamic light emission patterns respectively represent various stage production effects to be implemented by allowing light emission of a group of light-emitting devices 300 corresponding to the positions of individual seats in the seating layout.

The dynamic light emission patterns are video content that can be configured to reproduce a specific pattern repeatedly.

When a specific seating layout is selected from among at least one seating layout and a specific dynamic light emission pattern is selected from among a plurality of dynamic light emission patterns through the user interface, the processor 110 divides the seating layout of the venue into a plurality of sections based on the selected dynamic light emission pattern.

However, the seating layout of the venue is not necessarily divided based on the dynamic light emission pattern.

In an embodiment, the processor 110 may analyze the seating layout of the performance venue and divide it into a plurality of sections. Further details concerning the division of the seating layout will be described below.

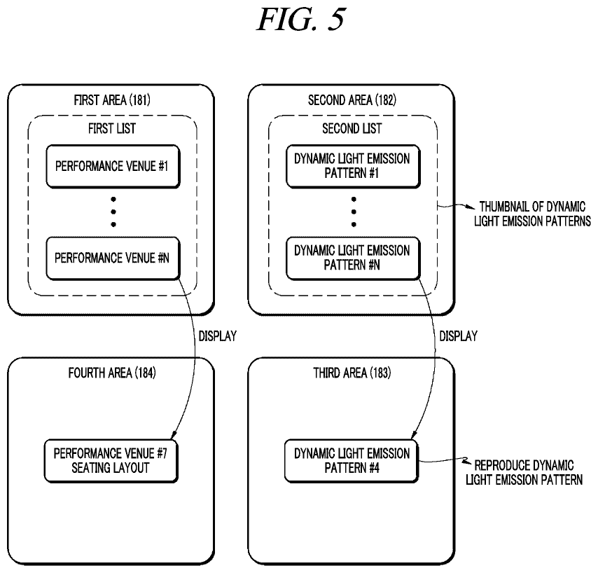

FIG. 5 is a diagram illustrating an example of a user interface for stage production effect simulation.

Referring to FIG. 5, the user interface includes a first area 181, a second area 182, a third area 183, and a fourth area 184.

The processor 110 displays, in the first area 181, a first list including at least one performance venue.

The processor 110 displays, in the second area 182, a second list including a plurality of dynamic light emission patterns.

The processor 110 displays, in the third area 183, a dynamic light emission pattern selected from the second list.

In an embodiment, the processor 110 displays a thumbnail of the dynamic light emission patterns in the second area 182. Then, when a specific dynamic light emission pattern is selected from the second list, the processor 110 may reproduce it in the third area 183.

The processor 110 may display, in the fourth area 184, the seating layout of the performance venue selected from the first list.

Likewise, the processor 110 may display a thumbnail of the seating layout of each performance venue in the first area 181, and may display, in the fourth area 184, the seating layout of the entire performance venue selected from the first list.

In an embodiment, the processor 110 applies the selected dynamic light emission pattern to each section based on predetermined conditions and then controls the user interface based on the application result. Thus, the processor 110 can simulate the reproduction of the dynamic light emission pattern.

Based on the result, the processor 110 may display a simulation image of the dynamic light emission pattern on the seating layout in the fourth area 184.

In an embodiment, the predetermined conditions may include at least one of duplication, mirroring, rotation, zoom-in, zoom-out, and color change.

The predetermined conditions are not limited to the above-described examples. In some embodiments, the predetermined conditions may also include changes in reproduction techniques such as reproduction speed or reverse reproduction.

For example, when a first performance venue and a first dynamic light emission pattern are selected, the processor 110 divides a seating layout of the first performance venue into a first section, a second section, and a third section.

The processor 110 may duplicate the first dynamic light emission pattern in the first section, mirror it vertically in the second section, and mirror it horizontally in the third section.

Then, the processor 110 may control the seating layout displayed in the fourth area 184 based on the application result. Accordingly, the dynamic light emission pattern can be output/displayed in the first, second, and third sections.

Accordingly, the user can view the stage production simulation displayed in the fourth area 184 and check how a performance would appear when produced with the first dynamic light emission pattern in the first performance venue.

In the above-described embodiments, the user interface is illustrated as being divided into four areas: the first area 181, the second area 182, the third area 183, and the fourth area 184, but it is not limited thereto.

For example, the processor 110 may display the first list in the first area 181. When a specific performance venue is selected from the first list, the processor 110 may display, in the first area 181, the second list of the second area 182. Then, when a specific dynamic light emission pattern is selected from the second area 182, the processor 110 may reproduce, in the second area 182, the dynamic light emission pattern of the third area 183.

In an embodiment, the display unit may include two image output devices. The processor 110 may divide a first image output device into three areas to display the first area 181, the second area 182, and the third area 183. Also, the processor 110 may display the fourth area 184 in a second image output device.

The configuration of the display unit and user interface can be implemented in various ways for user convenience. Thus, further details thereof will be omitted.

Hereinafter, the features of the present disclosure will be further described with reference to the accompanying drawings.

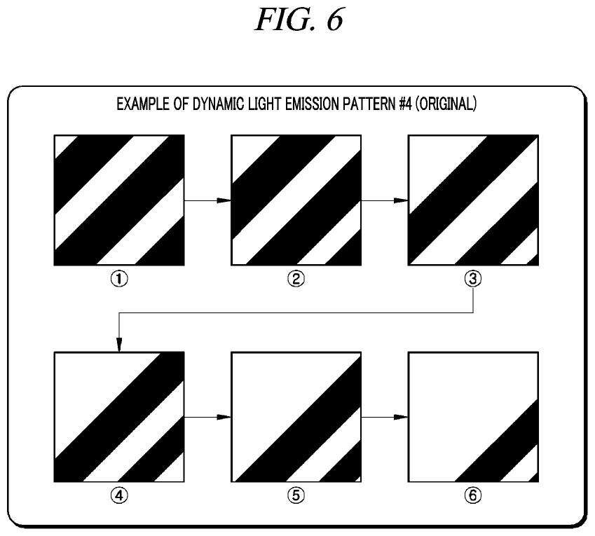

FIG. 6 is a diagram illustrating an example of dynamic light emission pattern #4. FIG. 6 shows how the dynamic light emission pattern moves.

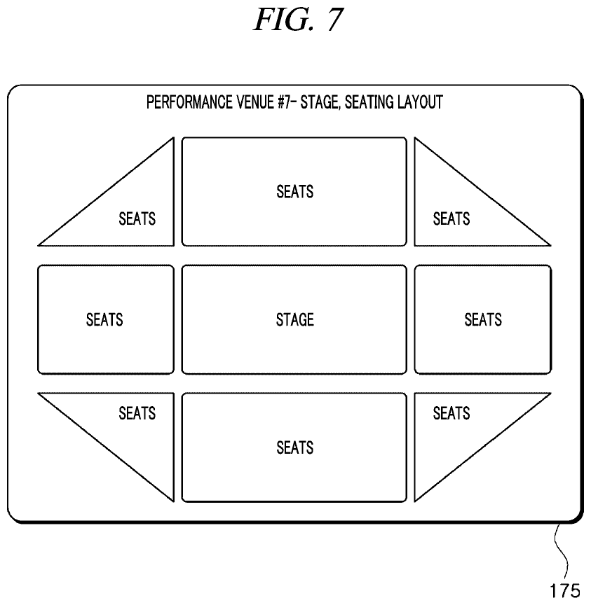

FIG. 7 is a diagram illustrating an example of a stage and a seating layout of performance venue #7 stored in the memory 150.

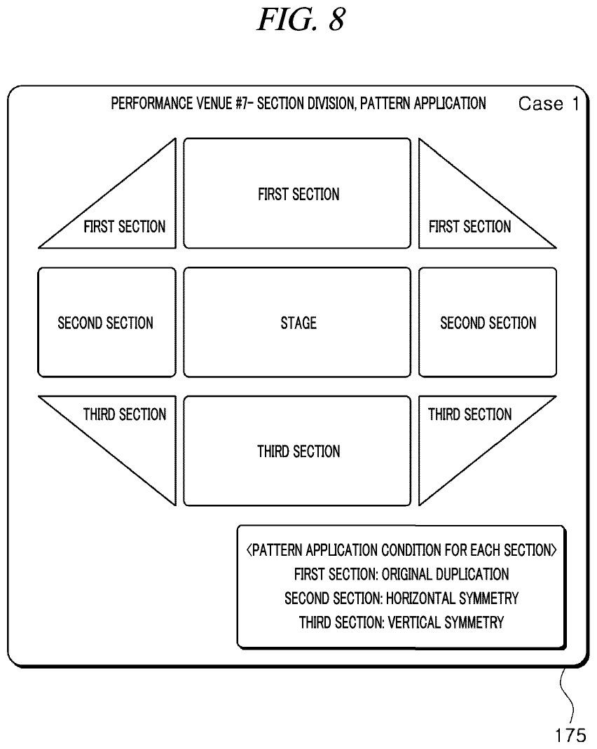

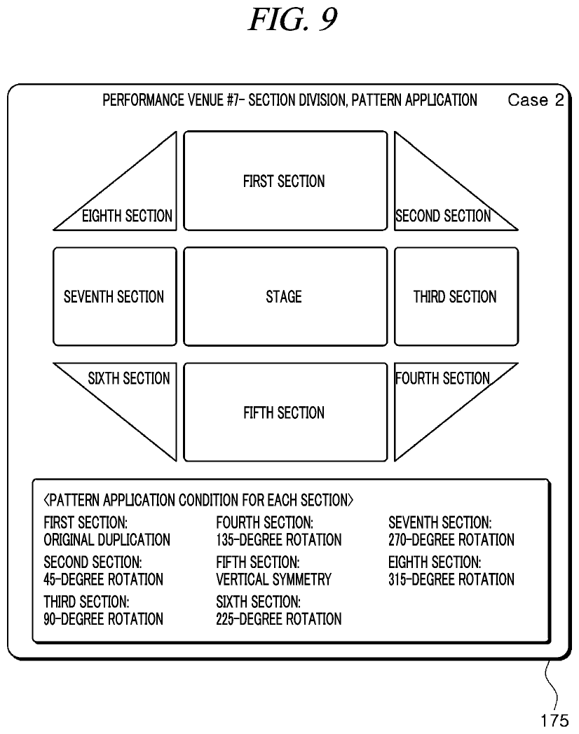

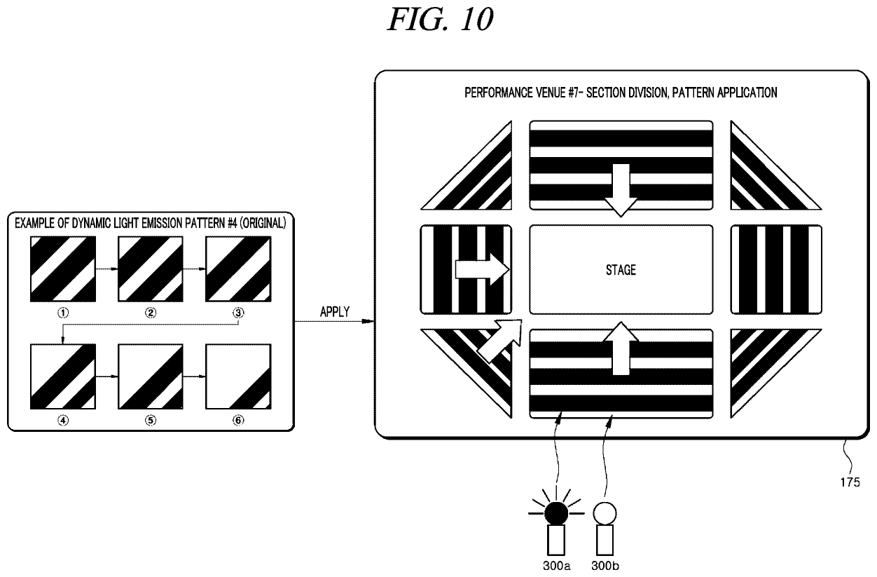

FIG. 8 and FIG. 9 are diagrams illustrating examples in which the seating layout of performance venue #7 is divided into a plurality of sections.

Referring to FIG. 7, performance venue #7 has a central stage surrounded by seats.

The processor 110 may divide the seating layout into three sections as shown in FIG. 8, or into eight sections as shown in FIG. 9.

As described above, the processor 110 may divide the seating layout based on the selected dynamic light emission pattern, or may analyze and divide the seating layout.

In an embodiment, the processor 110 may determine that a suitable stage production for performance venue #7 is to divide the seating layout into three sections as shown in FIG. 8, and apply the selected dynamic light emission pattern by duplicating it in the first section, mirroring it horizontally in the second section, and mirroring it vertically in the third section.

In an embodiment, the processor 110 may determine that a suitable stage production for performance venue #7 is to divide the seating layout into eight sections as shown in FIG. 9, and apply the selected dynamic light emission pattern to each section as depicted in FIG. 9.

The processor 110 may apply appropriate conditions to the respective sections by taking into account the seating layout of the performance venue and the characteristics of the dynamic light emission patterns.

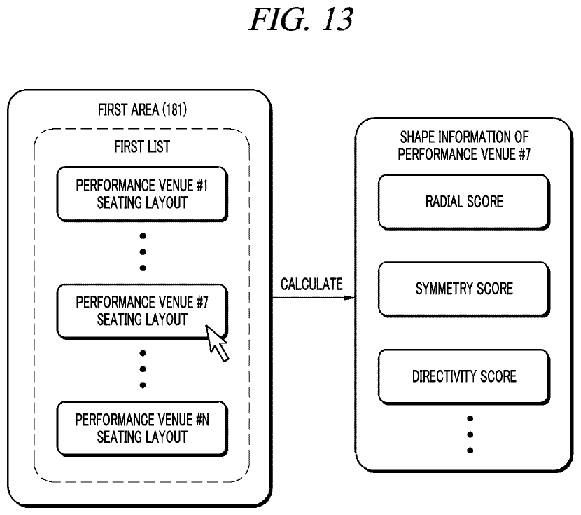

The stage production apparatus 100 according to the embodiments of the present disclosure will be described below with reference to FIG. 13 to FIG. 16 to illustrate an embodiment in which such appropriate conditions are applied.

FIG. 10 is a diagram illustrating an example in which dynamic light emission patterns are applied to the entire performance venue.

In the embodiments of the present disclosure, each light-emitting device 300 operates by repeatedly turning on (300a) and turning off (300b). However, the stage production apparatus 100 can simulate a stage production effect by applying dynamic light emission patterns to the entire performance venue. When these patterns are applied to the entire venue, the stage production apparatus 100 can provide a stage production effect as shown in FIG. 10.

Further, the processor 110 can provide a stage production effect suitable for the performance venue by controlling the user interface to implement the stage production effect on the divided seating layout of the venue.

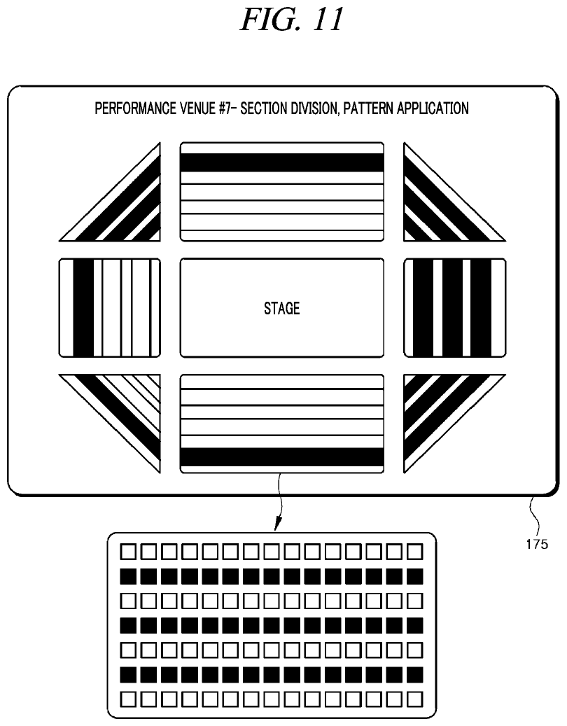

FIG. 11 is a diagram illustrating an example in which the light-emitting devices 300 located at the seats of the performance venue, as shown in FIG. 10, emit light in the form of pixels.

The light-emitting devices 300 located at the seats of the performance venue is arranged as shown in FIG. 11. Therefore, each light-emitting device 300 corresponds to a part of a pixel, and due to the large spacing between the devices, the visual output can be represented in various ways using a display device such as a monitor.

Accordingly, the stage production apparatus 100 according to the embodiments of the present disclosure can simulate stage production effects using various dynamic light emission patterns and apply them to an actual performance venue.

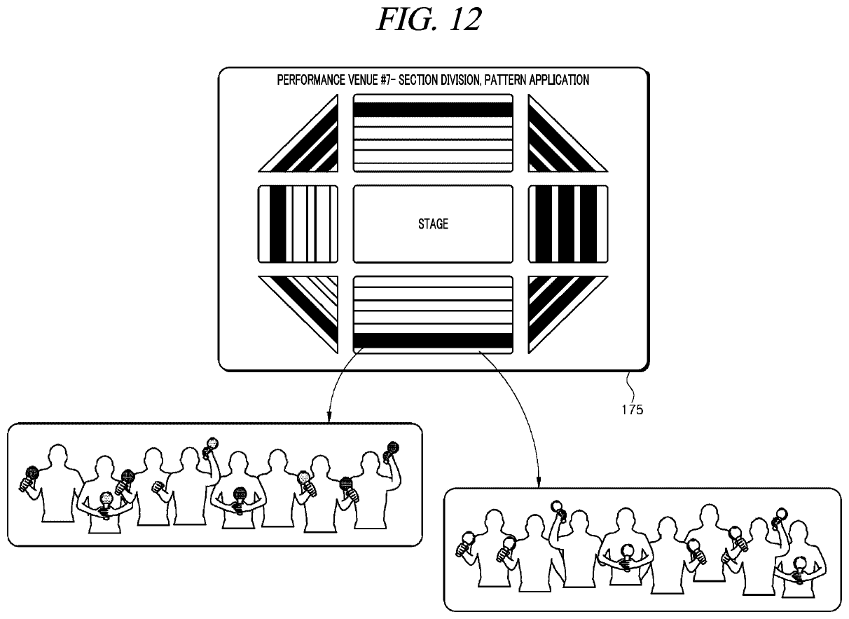

FIG. 12 is a diagram illustrating an example in which the light-emitting devices 300 held by audience members seated at the respective seats in the performance venue emit light under the conditions of light emission patterns shown in FIG. 10.

Referring to FIG. 12, the light-emitting device 300 can be held in various ways, such as in a person's left hand, right hand, or raised to head height. Other variables, including the device's battery status or any decorations, are also considered.

Conventionally, variations in luminous output caused by the variables described above have made it difficult to provide consistent and effective stage production effects.

However, the stage production apparatus 100 according to the embodiments of the present disclosure can simulate random pixel movements and brightness by controlling the light-emitting devices based on the postures and gestures of audience members.

In an embodiment, the processor 110 may determine the expected movements of the light-emitting devices based on a song's mood, tempo, and type, and then control the devices accordingly.

In an embodiment, each light-emitting device 300 may be equipped with a motion sensor, and the processor 110 may control the devices based on the data detected by the motion sensors.

Upon receiving motion data detected by the motion sensor within the light-emitting device 300, the processor 110 may generate a corresponding control signal and control the light-emitting device 300 based on the user's motion.

FIG. 13 is a diagram illustrating an example of calculating shape information of performance venue #7 selected through the user interface.

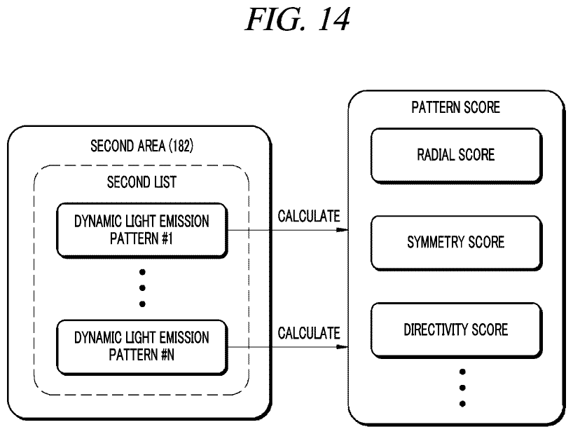

FIG. 14 is a diagram illustrating an example of calculating pattern scores of dynamic light emission patterns.

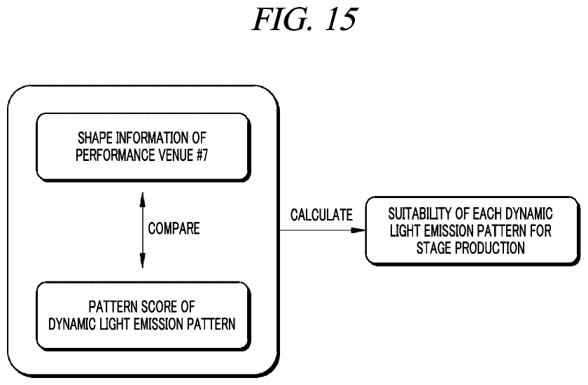

FIG. 15 is a diagram illustrating an example of calculating the suitability of each dynamic light emission pattern for stage production in performance venue #7.

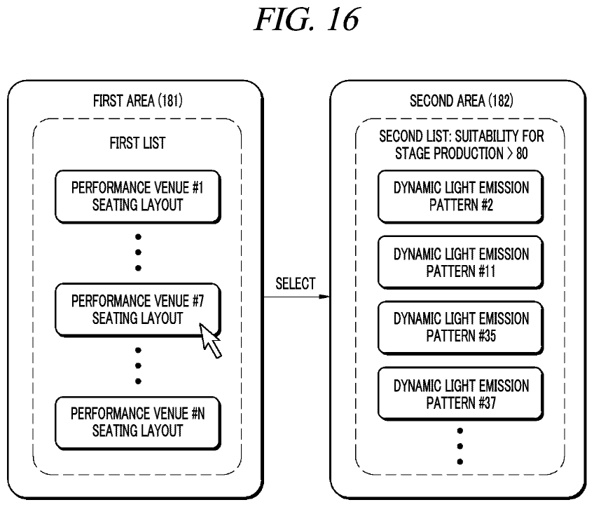

FIG. 16 is a diagram illustrating an example of displaying, in a second list, dynamic light emission patterns that satisfy predetermined suitability conditions based on the calculated suitability.

Referring to FIG. 13, the processor 110 may calculate the shape information of the performance venue based on the seating layout of the venue. The processor 110 may divide the seating layout of the venue into a plurality of sections based on the calculated shape information.

Herein, the shape information may include at least one of a radial score, a symmetry score, and a directivity score.

In an embodiment, the processor 110 may analyze only the shape of the seating layout when calculating the shape information, or it may perform the analysis by considering the relative positions between the stage and the seats.

For example, if the seats in the performance venue are arranged in only one direction from the stage, the processor 110 may determine that the seating layout has a high directivity score and low radial and symmetry scores.

In another embodiment, if the seats in the performance venue are arranged around the stage as shown in FIG. 7, the processor 110 may determine that the seating layout has high radial and symmetry scores and a low directivity score.

In yet another embodiment, if the seats in the performance venue are arranged to be symmetrical horizontally, vertically, or diagonally, the processor 110 may determine that the seating layout has a high symmetry score.

The above-described examples are only a few of many. The stage production apparatus 100 can calculate various types of shape information depending on the seating layout of the performance venue, the position of the stage, and the like.

Referring to FIG. 14, the processor 110 may calculate pattern scores including at least one of a radial score, a symmetry score, and a directivity score of the dynamic light emission patterns.

For example, the processor 110 may analyze the reproduction of the dynamic light emission patterns to calculate the degree of radial movement, symmetry, and directivity of each pattern.

Referring to FIG. 15, the processor 110 may compare the calculated shape information of the selected performance venue with the calculated pattern scores of each dynamic light emission pattern. Based on this comparison, the processor 110 can calculate the suitability of each dynamic light emission pattern for stage production in the venue.

For example, if the radial score of the shape information calculated for the first performance venue is low while the symmetry and directivity scores are high, the processor 110 may determine that dynamic light emission patterns with high symmetry and directivity scores are suitable for the first performance venue. Then, the processor may calculate a numerical score indicating the suitability for stage production.

Referring to FIG. 16, the processor 110 may display, in the second area 182, a second list including dynamic light emission patterns whose suitability for stage production satisfies predetermined conditions for the selected performance venue.

Specifically, when the first performance venue is selected from the first list displayed in the first area 181, the processor 110 calculates the shape score of the first performance venue. Then, the processor 110 calculates the pattern scores of the dynamic light emission patterns stored in the memory 150.

Then, the processor 110 compares the shape score calculated for the first performance venue with the pattern scores calculated for each dynamic light emission pattern. Based on this comparison, the processor 110 calculates the suitability of each dynamic light emission pattern for stage production in the first performance venue and displays the second list including only dynamic light emission patterns whose suitability satisfies predetermined conditions.

Through this function, the user can plan a stage production by simulating only the dynamic light emission patterns recommended as suitable for a specific performance venue, without the need to simulate every pattern.

In the embodiments of the present disclosure, the stage production apparatus may use a pre-trained artificial intelligence (AI) model to calculate the shape information of a performance venue and the pattern scores of dynamic light emission patterns.

In an embodiment, the processor 110 may train the AI model based on a training dataset in which at least one of a radial score, a symmetry score, and a directivity score is labeled for at least one performance venue.

In an embodiment, the processor 110 may train the AI model based on a training dataset in which at least one of a radial score, a symmetry score, and a directivity score is labeled for a plurality of dynamic light emission patterns.

In an embodiment, the processor 110 may train an AI model based on a training dataset in which a production suitability score, calculated from the shape score of at least one performance venue and the pattern scores of a plurality of dynamic light emission patterns, is labeled.

In an embodiment, the processor 110 may divide the seating layout of the performance venue into a plurality of sections based on the selected dynamic light emission pattern.

Specifically, the processor 110 may divide the seating layout of the performance venue into a plurality of sections based on the pattern scores of the selected dynamic light emission pattern.

For example, if the radial score among the pattern scores of the selected dynamic light emission pattern is higher than the symmetry and directivity scores, the processor 110 may divide the seating layout of the performance venue in a way that is suitable for producing a radial pattern.

For example, if the symmetry score among the pattern scores of the selected dynamic light emission pattern is higher than the radial and directivity scores, the processor 110 may divide the seating layout of the performance venue in a way that is suitable for producing a symmetrical pattern.

For example, if the directivity score among the pattern scores of the selected dynamic light emission pattern is higher than the symmetry and radial scores, the processor 110 may divide the seating layout of the performance venue in a way that is suitable for producing a directional pattern.

The above-described examples illustrate cases where one of the pattern scores is high for the sake of explanation. The processor 110 may divide the seating layout of the performance venue by considering a plurality of factors in the pattern scores.

In an embodiment, the stage production apparatus 100 may use an AI model to divide the seating layout of the performance venue.

For example, the processor 110 may construct a training dataset containing labeling information for the seating layout of at least one performance venue and for at least one dynamic light emission pattern suitable for each seating layout, and may train the AI model based on the training dataset.

Based on the training dataset, the AI model may learn how to divide the seating layout of the performance venue according to the pattern scores set for the dynamic light emission pattern.

In conclusion, the AI model may divide the seating layout of the performance venue into a plurality of sections to be suitable for producing the selected dynamic light emission pattern based on the pattern scores calculated for the dynamic light emission pattern and the seating layout of the venue.

In an embodiment, the stage production apparatus may utilize a plurality of AI models each configured to make a specific determination.

The method according to an embodiment of the present disclosure as descried above may be implemented as a program (or an application) to be executed in combination with a server as hardware, and may be stored in a storage medium.

The program may include codes coded in computer languages such as C, C++, JAVA, and machine language that the processor 110 (CPU) of the computer may read through a device interface thereof, in order for the computer to read the program and execute methods implemented using the program. The code may include a functional code related to a function defining functions required to execute the methods, and an execution procedure-related control code necessary for the processor 110 of the computer to execute the functions in a predetermined procedure. Moreover, the code may further include a memory reference-related code indicating a position (address) of an internal memory of the computer or the external memory 150 thereto in which additional information or media necessary for the processor 110 to execute the functions is stored. Furthermore, when the processor 110 of the computer needs to communicate with any other remote computer or server to execute the functions, the code may further include a communication-related code indicating how to communicate with any other remote computer or server using a communication module of the computer, and indicating information or media to be transmitted and received during the communication.

The storage medium means a medium that stores data semi-permanently, rather than a medium for storing data for a short moment, such as a register, a cache, or a memory, and that may be readable by a machine. Specifically, examples of the storage medium may include ROM, RAM, CD-ROM, a magnetic tape, a floppy disk, and an optical data storage device, but may not be limited thereto. That is, the program may be stored in various recording media on various servers to which the computer may access or on various recording media on the user's computer. Moreover, the medium may be distributed over the networked computer system 10 so that a computer readable code may be stored in a distributed scheme.

The processes of a method or algorithm described in connection with the embodiments disclosed herein may be embodied directly in hardware, in a software module executed by hardware, or in a combination of the two. The software module may reside in RAM (Random Access Memory), ROM (Read Only Memory), EPROM (Erasable Programmable ROM), EEPROM (Electrically Erasable Programmable ROM), flash memory, hard disk, a removable disk, a CD-ROM, or any other form of computer-readable storage medium known in the art.

Although an embodiment of the present disclosure are described with reference to the accompanying drawings, it will be understood by a person with ordinary skill in the art to which the present disclosure pertains that the present disclosure may be carried out in other detailed forms without changing the scope and spirit or the essential features of the present disclosure. Therefore, the embodiments described above are provided by way of example in all aspects, and should be construed not to be restrictive.

We claim:

1. A stage production simulation providing apparatus that uses dynamic light emission patterns, comprising:
a memory that stores at least one performance venue seating layout and a plurality of dynamic light emission patterns that respectively represents various stage production effects to be implemented by allowing light emission of a group of light-emitting devices corresponding to positions of individual seats in the at least one performance venue;
a display unit that displays a user interface configured to virtually implement the stage production effects corresponding to the dynamic light emission patterns on the seating layout; and
a processor that receives a control command corresponding to a specific control pattern requested from a lighting console device, and controls the user interface to simulate the stage production effect corresponding to the received control command,
wherein when a specific seating layout is selected from the at least one performance venue seating layout and a specific dynamic light emission pattern is selected from the dynamic light emission patterns through the user interface,
the processor divides the selected seating layout into a plurality of sections based on the selected dynamic light emission pattern, and controls the user interface to implement a stage production effect corresponding to the selected dynamic light emission pattern on the seating layout divided into the plurality of sections.

2. The stage production simulation providing apparatus of claim 1,
wherein the user interface includes:
a first area where a first list including the at least one performance venue is displayed;
a second area where a second list including the dynamic light emission patterns is displayed; and
a third area where a dynamic light emission pattern selected from the second list is displayed.

3. The stage production simulation providing apparatus of claim 2,
wherein the user interface further includes:
a fourth area where the selected seating layout is displayed.

4. The stage production simulation providing apparatus of claim 3,
wherein the processor applies the selected dynamic light emission pattern to each of the plurality of divided sections based on predetermined conditions and then controls the user interface based on the application result, and
the predetermined conditions include at least one of duplication, mirroring, rotation, zoom-in, zoom-out, and color change.

5. The stage production simulation providing apparatus of claim 4,
wherein based on the application result, the processor displays a simulation image of the dynamic light emission pattern on the seating layout in the fourth area.

6. The stage production simulation providing apparatus of claim 1,
wherein the processor identifies a plurality of areas dynamically changing within the selected dynamic light emission pattern, and
divides the selected seating layout into the plurality of sections respectively corresponding to the plurality of identified areas.

7. The stage production simulation providing apparatus of claim 2,
wherein the processor calculates shape information of the performance venue based on the selected seating layout, and divides the selected seating layout into a plurality of sections based on the shape information, and
the shape information includes at least one of a radial score, a symmetry score, and a directivity score.

8. The stage production simulation providing apparatus of claim 7,
wherein the processor calculates pattern scores including at least one of a radial score, a symmetry score, and a directivity score of the selected dynamic light emission pattern, and compares the calculated shape information of the specific performance venue with the calculated pattern scores, and
based on this comparison, the processor calculates the suitability of the selected dynamic light emission pattern for stage production in the specific performance venue.

9. The stage production simulation providing apparatus of claim 8,
wherein the processor displays, in the second area, the second list including dynamic light emission patterns whose suitability for stage production satisfies predetermined conditions.

10. A method for providing a stage production simulation using dynamic light emission patterns to be performed by a stage production apparatus, comprising:
a process of storing at least one performance venue seating layout and a plurality of dynamic light emission patterns that respectively represents various stage production effects to be implemented by allowing light emission of a group of light-emitting devices corresponding to positions of individual seats in the at least one performance venue;
a process of receiving a control command corresponding to a specific control pattern requested from a lighting console device; and
a process of controlling a user interface to simulate the stage production effect corresponding to the received control command,
wherein the process of controlling a user interface includes:
a process of displaying the user interface configured to virtually implement stage production effects corresponding to the dynamic light emission patterns on the at least one performance venue seating layout;
when a specific seating layout is selected from the at least one performance venue seating layout and a specific dynamic light emission pattern is selected from the dynamic light emission patterns through the user interface, a process of dividing the selected seating layout into a plurality of sections based on the selected dynamic light emission pattern; and
a process of controlling the user interface to implement a stage production effect corresponding to the selected dynamic light emission pattern on the seating layout divided into the plurality of sections.
